(19) United States
(12) Patent Application Publication
(10) Pub. No.: US 2009/0115464 A1
(43) Pub. Date: May 7, 2009

(54) MULTIPLE-BRANCHING CONFIGURATION FOR OUTPUT DRIVER TO ACHIEVE FAST SETTLING TIME

(75) Inventors: Richard Hernandez Garcia, Singapore (SG); Shao Hai Wu, Singapore (SG)

Correspondence Address: GREENBLUM & BERNSTEIN, P.L.C., 1950 ROLAND CLARKE PLACE, RESTON, VA, 20191, US

(73) Assignees: MATSUSHITA ELECTRIC INDUSTRIAL CO., LTD., Osaka (JP); PANASONIC SEMICONDUCTOR ASIA PTE., LTD., Singapore (SG)

(21) Appl. No.: 11/934,928

(22) Filed: Nov. 5, 2007

(51) Int. Cl. H03K 3/00

(52) U.S. Cl. 327/108

(57) ABSTRACT

A multiple branching configuration for output driver which achieves a fast settling time is provided. The multiple branching configuration comprises breaking down a typical output buffer stage into multiple branches; and utilizing multiple unit area sized transistors connected in parallel.

### BACKGROUND OF THE INVENTION

The present invention relates to achieving a quick settling time of an output Driver Output Signal under high frequency and high slew rate operation. An example of such an application is a CCD signal driver. More particularly, this invention relates to a method to allow the signal to be held stable while sampled by Analog Front End (AFE), mainly Analog-to-Digital-Converters (ADC).

In an exemplary application, a high Slew Rate CCD Buffer/Driver showing overshoot undershoot required to settle down to a variation of amplitude of less than 120 uVpp (for a 12 bit ADC sampling a Signal of 1 Vpp) during a sampling window of 0.8 ns. Generally, the settling time of a system depends on the damping ratio of the system and the magnitude of the excitation to the system. For Transistors, the settling time also depends on its Size, due to its parasitic components and the charging and discharging current of the parasitic components. In the case of an open-loop system, whereby there is no feed-back involved, settling time depends largely on Layout and circuit configuration of the system.

In Conventional Art, FIG. 1A, a High Speed Class AB Output Buffer Stage 101 is used to provide a high speed response at the output. In FIG. 1A, CC is a constant current source, Q1, Q2, Q3 and Q4 are transistors. Transistor Q1 defines an npn emitter follower arrangement, transistor Q2 defines a pnp emitter follower arrangement, and transistors Q3 and Q4 define a class AB output arrangement. An emitter area m of transistor Q1 is M. Thus, it is indicated m=M for transistor Q1. Similarly emitter area m of transistors Q2, Q3 and Q4 are, respectively, N, R and S. It is noted that each of emitter area sizes M, N, R and S is relatively large. The output Vout is connected to a capacitive load in series with a resistive load, as shown in FIG. 1C.

In this example, the Output Signal tends to show Variations of more than 100 uV which is to be due to the large parasitic Capacitance present in the single large Output Transistors. FIG. 1B illustrates an example of the variation described and this variation is also known as “Ringing” effect. Technically, settling time of this “Ringing” effect is directly related to the parasitic Capacitance of the device.

### SUMMARY OF THE INVENTION

The purpose of this invention is to provide a method to provide a stable signal (variation of less than 100 uV) during sampling by an ADC (12-bit) without increasing the ICQ greatly while maintaining a reasonable change in size.

According to a conventional output stage, FIG. 1A, a single Large Class AB Output Buffer Stage 101 is used. Due to the large Device used, the parasitic components, mainly the parasitic capacitance, present would be large, resulting in a long settling time.

The invention proposed here indicates a topology to reduce further the settling time by splitting the single Large Class AB Output Stage into several branches, where the device size of each branch multiplied by the number of branches used in the multiple-branched Output Stage is the same as the sum of devices used in the Large Single Output Stage. In FIG. 2A, a multiple branched system is used for illustration.

From a system point of view, by splitting the Output Stage into several branches, each branch will incur “Ringing” effect of different magnitude and phase. As the output is common, there will be an averaging effect due to different phase and magnitude. This effect can be observed better on the actual chip compared to in simulation.

This topology can be further modified to reduce the magnitude of the variation, or “Ringing” by having different sizing on the components while maintaining the same component counts. Meaning, we can further improve the performance by having a different ratio between the different branches. In the Second Preferred Embodiment, FIG. 3, the ratio of the 2 branches is based on the ratio is 1:2.

Further explanation accompanied by simulation results will be presented in the following detailed description.

### BRIEF DESCRIPTION OF THE DRAWINGS

FIGS. 1A, 1B and 1C are diagrams showing the conventional art of the application for a high speed output stage buffer;

FIG. 2A is a circuit diagram of the first preferred embodiment, according to the present invention.

FIG. 2B is a circuit diagram of the second preferred embodiment, according to the present invention.

FIG. 3 is a circuit diagram of the third preferred embodiment, according to the present invention.

FIGS. 4A, 4B and 4C are illustrations of the inductive effect of an emitter-follower using npn transistor.

FIGS. 5A and 5B are illustrations of the averaging effect of using a multiple branching topology.

FIGS. 6A and 6B are illustrations of the usage of multiple parallel-connected unit sized transistors.

### DETAILED DESCRIPTION OF THE PREFERRED EMBODIMENTS

Before describing the embodiments of the present invention, the basic concept of the invention is first explained.

The present invention provides a stable signal (variation of less than 100 uV for a 12-bit ADC) during sampling by an ADC (12-bit ADC) without increasing the ICQ greatly while maintaining a reasonable change in size.

Technically, the settling time of the output signal depends on several factors, mainly, the parasitic components, the current flowing through the device, the magnitude of the excitation (overshoot or undershoot), and load property. To make clear the principle used behind the present invention, an explanation of the theory involved will first be furnished:

In the case of an emitter follower (Class AB Output Transistors are connected in emitter follower configuration), the settling time of the output signal largely depends on the nature of its Output Impedance, Zout.

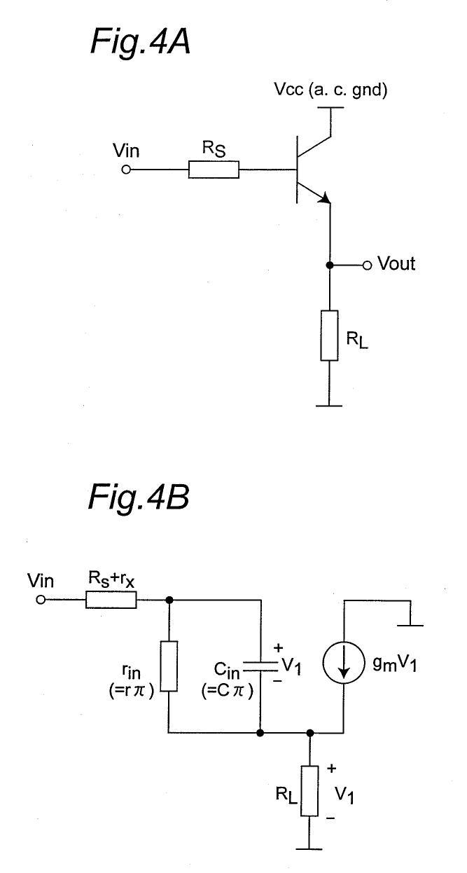

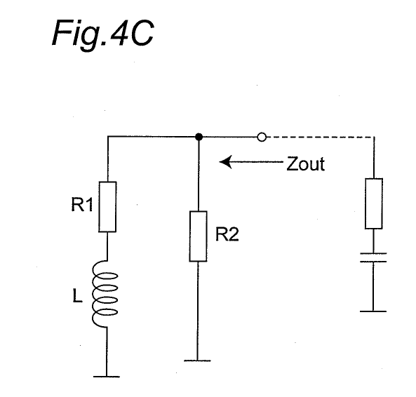

FIG. 4A shows an npn emitter follower used to illustrate the Zout nature of an emitter follower. Technically, the emitter follower can be redrawn in its small signal diagram as shown in FIG. 4B. By small signal analysis,

Zout=(Z_{π}+Rₛ+r_{b})/(1+gmZ_{π})

Where,
Zπ=r_{π}/(1+sC_{π}r_{π})
r_{b}=base resistance
Rₛ=Source resistance

At low frequency, Z_{π}=r_{π}, and Zout≈(1/gm)+(Rₛ+r_{b})/βₒ (Eqn. 1)

At high frequency, Z_{π}≈0, Zout≈Rₛ+r_{b} (Eqn. 2)

At very low collector current, 1/gm is large. If (1/gm)>(Rₛ+r_{b}), comparing (1) and (2) shows that |Zout| decreases as frequency increases and Zout therefore appears capacitive. In an application of the present invention, a very low collector current (uA) flows through the output transistors of the Output Buffer Stage when the signal is stable, or at constant signal level.

At high collector current, 1/gm is small. Usually, (1/gm)<(Rₛ+r_{b}), comparing (1) and (2) shows that |Zout| increases as frequency increases and Zout therefore appears inductive. In an application of the mentioned invention, a high collector current (mA) flows through the output transistors of the Output Buffer Stage when there is a change in signal level.

FIG. 4C shows an equivalent circuit of Zout seen at the output transistors of the Output Buffer Stage of the npn emitter follower in FIG. 4A, where:

R1=(1/gm)+(Rₛ/βₒ)=Zout (at low frequency), from Eqn. 1

R2=Rₛ=Zout (at high frequency), from Eqn. 2

L=C_{π}r_{π}(Rₛ/βₒ) (a typical inductance component for the output impedance of an emitter follower)

Assuming Rₛ>>r_{b} for all cases.

In the application of the present invention, a capacitive load is connected, and a RLC circuit is thus formed. This RLC circuit will contribute to the “ringing” of the Output Signal. It is an objective of the present invention to make reduce the overall ‘ringing’ effect by reducing the magnitude of these components.

The current invention indicates a topology to reduce the settling time by breaking the Class AB Output Buffer Stage 101 into several branches, where the total device size of the branches used in the multiple-branch Output Buffer Stage is the same as the initial device size used in the initial Output Buffer Stage.

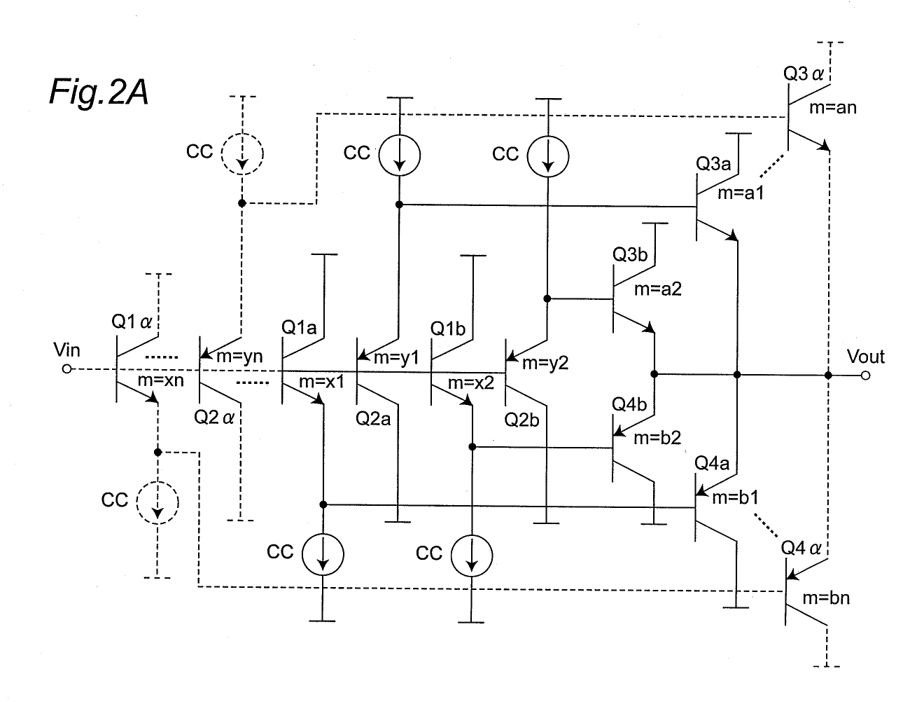

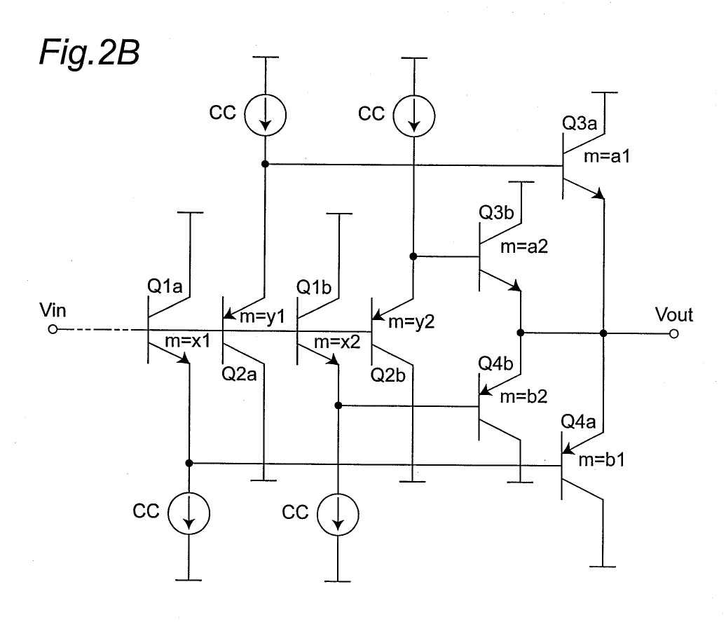

Referring to FIG. 2A, the first preferred embodiment according to the present invention is shown, where n branches are constructed. The relationship between the transistors of the two topologies (with and without branching) and the emitter area sizes are as follows. Here, m=emitter area size.

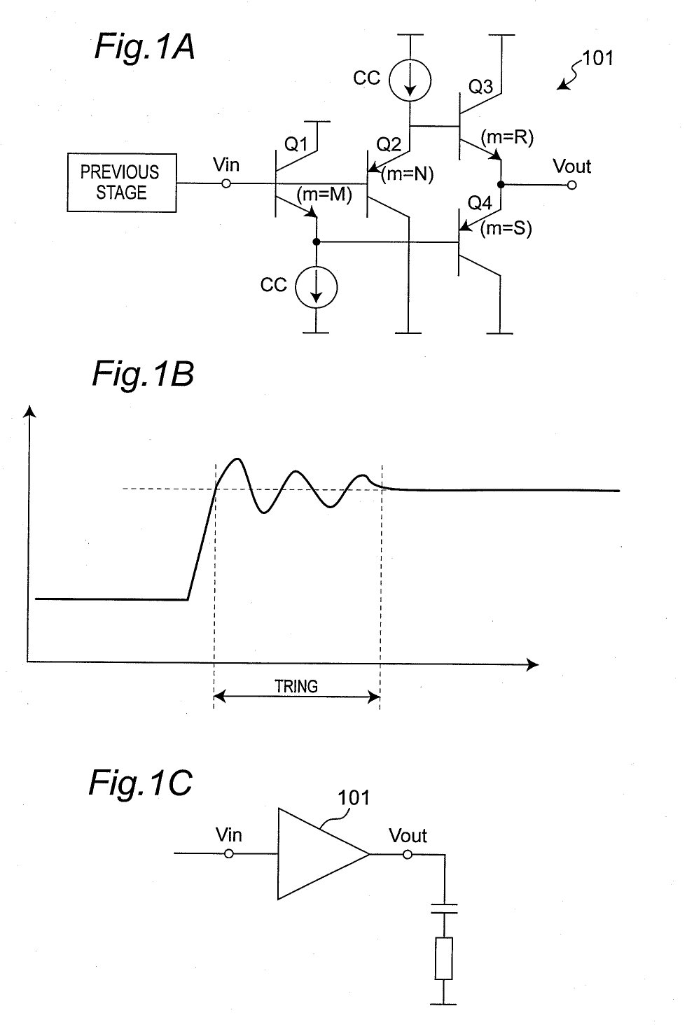

In place of transistor Q1 shown in FIG. 1A, the first embodiment uses a plurality of transistors Q1a, Q1b, . . . Q1α, where Q1α is an nth branch component of Q1. A constant current source CC is provided to each transistor.

In place of transistor Q2 shown in FIG. 1A, the first embodiment uses a plurality of transistors Q2a, Q2b, . . . Q2α, where Q2α is an nth branch component of Q2. A constant current source CC is provided to each transistor.

In place of a pair of transistors Q3 and Q4 shown in FIG. 1A, the first embodiment uses a plurality of pairs of transistors (Q3a and Q4a), (Q3b and Q4b), . . . (Q3α and Q4α) where (Q3α and Q4α) is an nth branch component of a transistor pair (Q3 and Q4).

In other words, according to the present invention, a plurality of npn emitter follower sub-arrangements Q1a, Q1b, . . . Q1α are provided and connected in parallel to each other. Such a plurality of npn emitter follower sub-arrangements Q1a, Q1b, . . . Q1α taken together define the npn emitter follower arrangement, which corresponds to transistor Q1 shown in FIG. 1A. As explained above, transistor Q1 has an emitter size M. In the first embodiment, the emitter size M is divided into n pieces of emitter sizes x1, x2, x3, xn which are used as emitter sizes for transistors Q1a, Q1b, . . . Q1α, respectively. As one example, emitter sizes for transistors Q1a, Q1b, . . . Q1α can be the same. In this case, x1=x2=x3 . . . =xn, and M/n=x1. In another example emitter sizes for transistors Q1a, Q1b, . . . Q1α are different, or are grouped into different sizes.

Thus, transistor Q1 is branched or separated into Q1a, Q1b, . . . Q1α, (where Q1α=nth branch component of Q1), with m=M=x1+x2+ . . . +xn (values of x2, . . . , xn are multiples of x1, where x1 is a positive Real number).

Similarly, according to the present invention, a plurality of pnp emitter follower sub-arrangements Q2a, Q2b, . . . Q2α are provided and connected in parallel to each other. Such a plurality of pnp emitter follower sub-arrangements Q2a, Q2b, . . . Q2α taken together define the pnp emitter follower arrangement, which corresponds to transistor Q2 shown in FIG. 1A.

Thus, transistor Q2 is branched or separated into Q2a, Q2b, . . . Q2α, (where Q2α=nth branch component of Q2), with m=N=y1+y2+ . . . +yn (values of y2, . . . , yn are multiples of y1, where y1 is a positive Real number).

Similarly, according to the present invention, a plurality of class AB output sub-arrangements (Q3a and Q4a), (Q3b and Q4b), . . . (Q3α and Q4α) are provided and connected in parallel to each other. Such a plurality of class AB output sub-arrangements (Q3a and Q4a), (Q3b and Q4b), . . . (Q3α and Q4α) taken together define the class AB output arrangement, which corresponds to transistors Q3 and Q4 shown in FIG. 1A.

Thus, transistor Q3 is branched or separated into Q3a, Q3b, . . . Q3α, (where Q3α=nth branch component of Q3), with m=R=a1+a2+ . . . +an (values of a2, . . . , an are multiples of a1, where a1 is a positive Real number).

Thus, transistor Q4 is branched or separated into Q4a, Q4b, . . . Q4α, (where Q4α=nth branch component of Q4), with m=S=b1+b2+ . . . +bn (values of b2, . . . , bn are multiples of b1, where b1 is a positive Real number).

Referring to FIG. 2B, a second embodiment is shown. In this second preferred embodiment, a doubled branched system is used as an example of an implementation of the multiple-branch Output Buffer Stage. Here, the Class AB Output Buffer Stage is split into 2 branches. The Output Buffer Stage drives an AFE, Analog Front End, modeled as a capacitive load in series with a resistive load, as earlier described (referring to FIG. 1C).

For the exemplary embodiment shown in FIG. 2B, the relationship between the transistors of the two topologies (with and without branching) and the emitter area sizes are as follows, where m=emitter area size:

Q1 is branched into Q1a and Q1b, with m=M=x1+x2 (value of x2 is a multiple of x1, where x1 is a positive Real number);

Q2 is branched into Q2a and Q2b, with m=N=y1+y2 (value of y2 is a multiple of y1, where y1 is a positive Real number);

Q3 is branched into Q3a and Q3b, with m=R=a1+a2 (value of a2 is a multiple of a1, where a1 is a positive Real number);

Q4 is branched into Q4a and Q4b, with m=S=b1+b2 (value of b2 is a multiple of b1, where b1 is a positive Real number).

From a system point of view, splitting the Output Stage into several branches allows reduction of the “Ringing” caused by the parasitic components due to the following reason: During Operation, each branch will incur “Ringing” effect of different magnitude and phase. As the output node of each branch is common, i.e. they share the same output, the “Ringing” effects will be averaged effect due to each branch's different phase and magnitude. Generally, the effect describe above can be observed better using the actual chip compared to in simulation as they are more layout dependent effects.

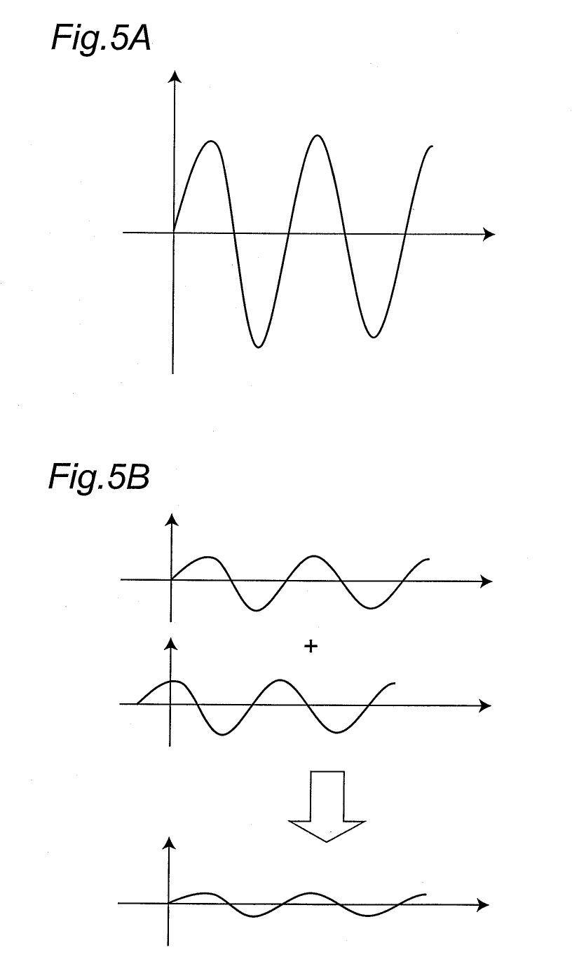

FIGS. 5A and 5B show illustrations of the averaging effects mentioned above.

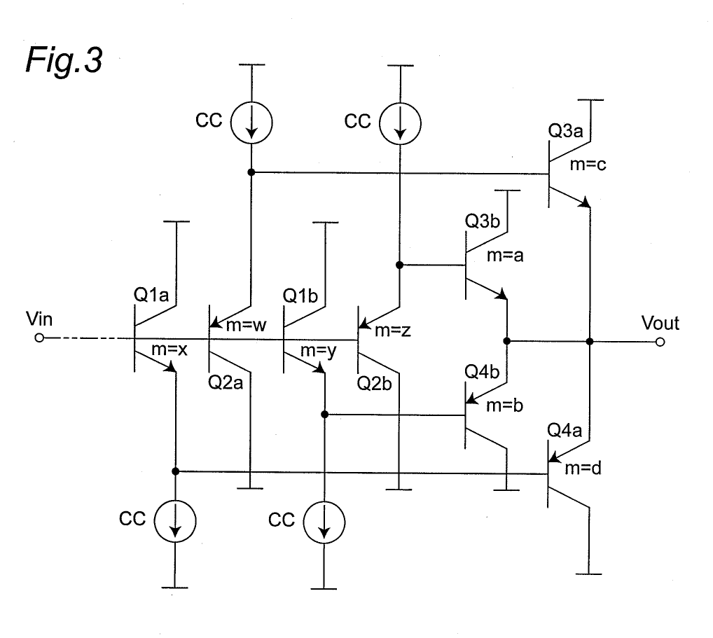

Referring to FIG. 3, the third preferred embodiment of the present invention is described. The branching topology as described for the first and second embodiments can be further improved to reduce the magnitude of the variation, or “Ringing” by having different sizing on the components while maintaining the same component counts. Meaning, we can further improve the performance by having a different ratio between the different branches.

For the third preferred embodiment shown in FIG. 3, the relationship between the emitter area sizes are as follows:

x1≠x2;

y1≠y2;

a1≠a2;

b1≠b2.

The fourth preferred embodiment assigns the ratio of the 2 branches based on the ratio 1:2. Referring to FIG. 3 again, for the fourth embodiment, the relationship between the emitter area sizes are as follows:

x1=2*(x2);

y1=2*(y2);

a1=2*(a2);

b1=2*(b2).

As mentioned in the beginning of this section, there is an RLC circuit contributing to the “Ringing”. By reducing the inductive nature of Zout, the variation seen at the output signal will be at a high frequency, but at smaller magnitude. From FIG. 4C, the inductive nature of the Output Impedance can be related to its parasitic capacitance by L=C_{π}r_{π}(Rₛ/βₒ). By splitting the transistor into several branches, the parasitic capacitance, C_{π} can be reduced, hence decreasing the inductive nature. Also, by having the 2 branches to have different sizing, the RLC circuit would experience different settling time and magnitude. This will further average out the variation at the output signal. In the fourth preferred embodiment, a ratio of 1:2 is used for a 2 branched system. This ratio is chosen as it would ensure the difference in the inductive nature between the two branches to be about twice, allowing a smoother averaging effect to between the two branches.

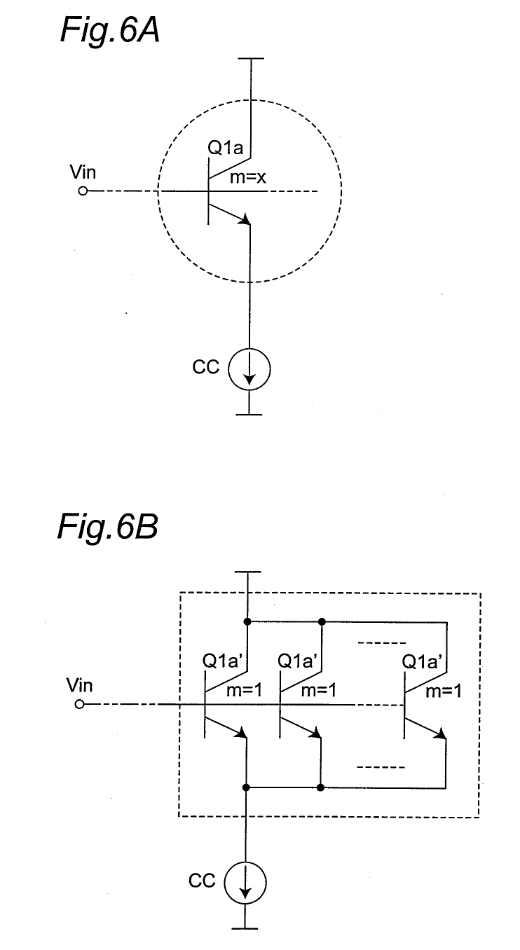

FIGS. 6A and 6B show the fifth preferred embodiment according to the present invention. Multiple unit transistors are arranged in parallel to obtain an equivalent emitter area of the initial transistor. Hence, as an example, based on the third preferred embodiment, to construct Q1a, multiple Q1a′ are combined in parallel such that the emitter area of Q1a′ is a unit area.

Hence, for emitter area, m=x,

Number of Q1a′ to combine in parallel=x/1

According to the present invention, an output driver with less “Ringing” effect can be provided without substantially increasing the chip size of the integrated circuit, because the emitter size is maintained substantially the same even if the number of sub-arrangement increases.

What is claimed is:

1. A multiple branching configuration for output driver comprising:
multiple additional output buffer stage branches to provide multiple paths for the input signal.

2. A multiple branching configuration for output driver as described in claim 1, wherein said multiple additional output buffer stage branches equals to two.

3. A multiple branching configuration for output driver as described in claim 1, wherein said multiple additional output buffer stage branches comprise:
transistors in one of said branches have emitter area sizes not equal to that of another of said branches.

4. A multiple branching configuration for output driver as described in claim 2, wherein said multiple additional output buffer stage branches comprise:
transistors in one of said branches have emitter area sizes not equal to that of another of said branches.

5. A multiple branching configuration for output driver as described in claim 1, wherein said multiple additional output buffer stage branches comprise:
transistors of said branches consist of unit area sized transistors connected in parallel.

6. A multiple branching configuration for output driver as described in claim 5, wherein said multiple additional output buffer stage branches comprise:
transistors in one of said branches have emitter area sizes not equal to that of another of said branches.

7. A multiple branching configuration for output driver as described in claim 4, wherein said output driver drives a CCD signal.

8. A multiple branching configuration for output driver as described in claim 6, wherein said output driver drives a CCD signal.

9. An output driver having an npn emitter follower arrangement, a pnp emitter follower arrangement and a class AB output arrangement, said output driver comprising:
a plurality of npn emitter follower sub-arrangements connected in parallel and defining said npn emitter follower arrangement;
a plurality of pnp emitter follower sub-arrangements connected in parallel and defining said pnp emitter follower arrangement; and
a plurality of class AB output sub-arrangements connected in parallel and defining said class AB output arrangement.
